(19) United States
(12) Patent Application Publication
(10) Pub. No.: US 2025/0312883 A1
(43) Pub. Date: Oct. 9, 2025

(54) POLISHING METHOD AND POLISHING APPARATUS

(71) Applicant: EBARA CORPORATION, Tokyo (JP)

(72) Inventor: Masaki KINOSHITA, Tokyo (JP)

(21) Appl. No.: 19/092,869

(22) Filed: Mar. 27, 2025

(30) Foreign Application Priority Data
Apr. 2, 2024 (JP) 2024-059356

(51) Int. Cl. B24B 37/013; B24B 49/12; G01B 11/06

(52) U.S. Cl. CPC B24B 37/013; B24B 49/12; G01B 11/0625

(57) ABSTRACT

A polishing method that can stabilize an intensity of light emitted by a flash light source and can polish a substrate while measuring film thickness at more measurement points is disclosed. The polishing method includes: causing a first flash light source and a second flash light source to emit light multiple times at different timings to cast the light on the substrate through an optical sensor head while the optical sensor head is moving across the substrate, and capture reflected light from the substrate through the optical sensor head by a spectrometer; generating a spectrum of the reflected light; and determining a film thickness of the substrate from the spectrum.

### CROSS REFERENCE TO RELATED APPLICATION

This document claims priority to Japanese Patent Application No. 2024-059356 filed Apr. 2, 2024, the entire contents of which are hereby incorporated by reference.

### BACKGROUND

Manufacturing processes for semiconductor devices include various steps, such as polishing an insulating film (e.g., SiO₂) and polishing a metal film (copper or tungsten). A wafer is polished using a polishing apparatus. The polishing apparatus typically includes a polishing table that supports a polishing pad, a polishing head that presses the wafer against the polishing pad, and a slurry supply nozzle that supplies slurry onto the polishing pad. While the polishing table is rotated, the slurry is supplied onto the polishing pad on the polishing table, and the polishing head presses the wafer against the polishing pad. The wafer is brought into sliding contact with the polishing pad in the presence of the slurry. The surface of the wafer is planarized by a combination of a chemical action of the slurry and a mechanical action of the polishing pad and abrasive grains contained in the slurry.

Polishing of the wafer is terminated when a thickness of a film (such as an insulating film, a metal film, or a silicon layer) constituting the surface of the wafer reaches a predetermined target value. The polishing apparatus typically includes an optical film-thickness measuring system for measuring a thickness of a non-metallic film, such as an insulating film or a silicon layer. This optical film-thickness measuring system is configured to direct light from an optical sensor head to the surface of the wafer while the optical sensor head is rotating together with the polishing table, measure intensity of the light reflected from the wafer with a spectrometer, and analyze a spectrum of the reflected light to measure the film thickness of the wafer.

FIG. 7 is a schematic diagram showing an example of a plurality of measurement points for the film thickness measured by the optical film-thickness measuring system. As shown in FIG. 7, an optical sensor head 500 irradiates a plurality of measurement points MP with light while moving across a surface of a wafer W. The optical sensor head 500 is coupled to a flash light source (not shown), and the light emitted by the flash light source is transmitted to the optical sensor head 500. Each time the optical sensor head 500 sweeps across the surface of the wafer W, the film thickness at the plurality of measurement points MP is measured as shown in FIG. 7.

As can be seen from FIG. 7, the more measurement points MP on the wafer W, the more precise a film-thickness distribution (or film-thickness profile) can be obtained. However, if a light emission cycle of the flash light source is shortened, the intensity of light emitted by the flash light source may vary due to a light emission mechanism of the flash light source. In other words, if the light emission cycle of the flash light source is too short, a power energy stored in the flash light source for light emission is not stable, and as a result, the intensity of the light emitted by the flash light source becomes unstable.

### SUMMARY

Therefore, there are provided a polishing method and a polishing apparatus that can stabilize an intensity of light emitted by a flash light source and can polish a substrate while measuring film thickness at more measurement points.

Embodiments, which will be described below, relate to a polishing method and a polishing apparatus for polishing a substrate, such as a wafer, and more particularly to a polishing method and polishing apparatus for polishing a substrate while measuring the film thickness of the substrate with an optical film-thickness measuring system.

In an embodiment, there is provided a polishing method of polishing a substrate, comprising: rotating a polishing table together with an optical sensor head, the optical sensor head being optically coupled to a spectrometer, a first flash light source, and a second flash light source; while moving the optical sensor head across the substrate, polishing the substrate by pressing the substrate with a polishing head against a polishing pad on the polishing table; causing the first flash light source and the second flash light source to emit light multiple times at different timings to cast the light on the substrate through the optical sensor head while the optical sensor head is moving across the substrate, and capture reflected light from the substrate through the optical sensor head by the spectrometer; generating a spectrum of the reflected light; and determining a film thickness of the substrate from the spectrum.

In an embodiment, the first flash light source and the second flash light source alternately emit the light while the optical sensor head is moving across the substrate.

In an embodiment, the optical sensor head is comprised of an end of a light-emitting optical fiber cable and an end of a light-receiving optical fiber cable, the light-emitting optical fiber cable is coupled to a plurality of branch optical fiber cables, and the first flash light source and the second flash light source are coupled to the plurality of branch optical fiber cables, respectively.

In an embodiment, there is provided a polishing apparatus for polishing a substrate, comprising: a polishing table configured to support a polishing pad; a table motor configured to rotate the polishing table; an optical sensor head disposed in the polishing table; a spectrometer, a first flash light source, and a second flash light source optically coupled to the optical sensor head; a polishing head configured to press the substrate against the polishing pad to polish the substrate; and an operation controller configured to control operations of the spectrometer, the first flash light source, and the second flash light source, the operation controller being configured to: instruct the first flash light source and the second flash light source to emit light multiple times at different timings to cast the light through the optical sensor head on the substrate while the optical sensor head is moving across the substrate, and instruct the spectrometer to capture reflected light from the substrate through the optical sensor head; generate a spectrum of the reflected light; and determine a film thickness of the substrate from the spectrum.

In an embodiment, the operation controller is configured to instruct the first flash light source and the second flash light source to alternately emit the light while the optical sensor head is moving across the substrate.

In an embodiment, the optical sensor head is comprised of an end of a light-emitting optical fiber cable and an end of a light-receiving optical fiber cable, the light-emitting optical fiber cable is coupled to a plurality of branch optical fiber cables, and the first flash light source and the second flash light source are coupled to the plurality of branch optical fiber cables, respectively.

Since the plurality of flash light sources including at least the first flash light source and the second flash light source are used, the light emission cycle of each of the first flash light source and the second flash light source can be increased. As a result, the intensity of the light emitted by each of the first flash light source and the second flash light source is stabilized. Furthermore, since the light is emitted multiple times by both the first flash light source and the second flash light source while the optical sensor head is moving across the substrate once, the film thickness of the substrate can be measured at many measurement points.

### BRIEF DESCRIPTION OF THE DRAWINGS

FIG. 1 is a schematic diagram illustrating an embodiment of a polishing apparatus;

FIG. 2 is a cross-sectional view showing a detailed configuration of an embodiment of the polishing apparatus shown in FIG. 1;

FIG. 3 is a time chart showing an embodiment of light-emission operations of a first flash light source and a second flash light source and reflected-light capturing operation of a spectrometer;

FIG. 4 is a diagram showing an example of light irradiation points on a surface of a wafer;

FIG. 5 is a schematic diagram illustrating an embodiment of an optical film-thickness measuring system having three flash light sources;

FIG. 6 is a time chart showing an embodiment of light-emission operations of the three flash light sources and reflected-light capturing operation of the spectrometer; and

FIG. 7 is a diagram showing an example of measurement points for film thickness of a wafer.

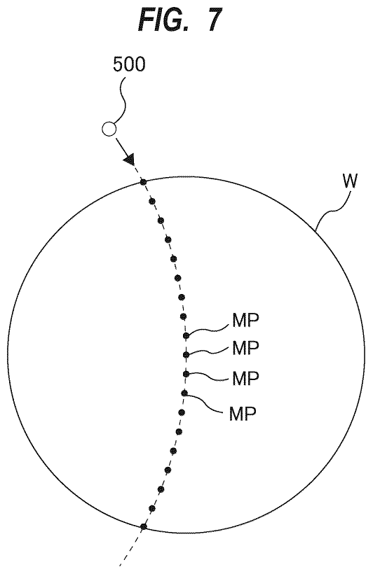

### DESCRIPTION OF EMBODIMENTS

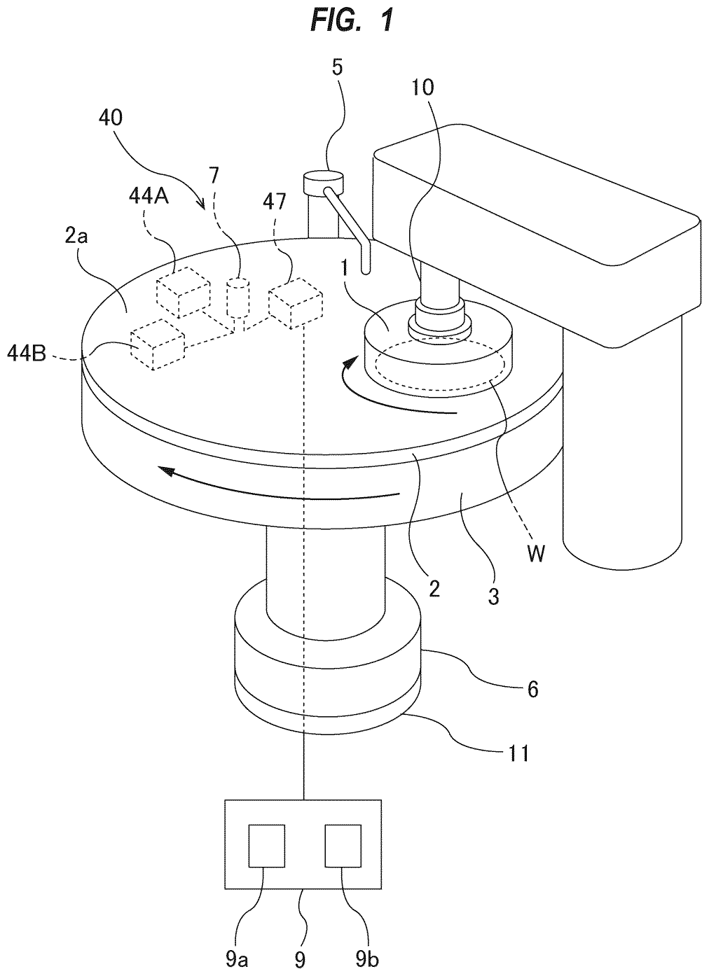

Embodiments will be described with reference to the drawings. FIG. 1 is a schematic diagram showing an embodiment of a polishing apparatus. As shown in FIG. 1, the polishing apparatus includes a polishing table 3 configured to support a polishing pad 2 thereon, a polishing head 1 configured to press a wafer W, which is an example of a substrate, against the polishing pad 2, a table motor 6 configured to rotate the polishing table 3, and a slurry supply nozzle 5 configured to supply a slurry onto the polishing pad 2.

The polishing head 1 is coupled to a head shaft 10, and the polishing head 1 rotates together with the head shaft 10 in a direction indicated by arrow. The polishing table 3 is coupled to the table motor 6, which is configured to rotate the polishing table 3 and the polishing pad 2 in a direction indicated by arrow. The polishing apparatus includes a rotary encoder 11 configured to detect a rotation angle of the polishing table 3. The rotary encoder 11 is coupled to the table motor 6.

The wafer W is polished as follows. While the polishing table 3 and the polishing head 1 are rotated in the direction shown by the arrow in FIG. 1, the slurry is supplied from the slurry supply nozzle 5 onto a polishing surface 2a of the polishing pad 2 on the polishing table 3. While the wafer W is rotated by the polishing head 1, the wafer W is pressed against the polishing surface 2a of the polishing pad 2 with the slurry present on the polishing pad 2. The surface of the wafer W is polished by a chemical action of the slurry and a mechanical action of the polishing pad 2 and abrasive grains contained in the slurry.

The polishing apparatus includes an optical film-thickness measuring system 40 for measuring a film thickness of the wafer W. The optical film-thickness measuring system 40 includes an optical sensor head 7, a first flash light source 44A, a second flash light source 44B, a spectrometer 47, and an operation controller 9. The optical sensor head 7, the first flash light source 44A, the second flash light source 44B, and the spectrometer 47 are attached to the polishing table 3 and rotate together with the polishing table 3 and the polishing pad 2. A position of the optical sensor head 7 is such that the optical sensor head 7 moves across the surface of the wafer W on the polishing pad 2 each time the polishing table 3 and the polishing pad 2 make one rotation.

The operation controller 9 is composed of at least one computer. The operation controller 9 includes a memory 9a storing programs therein for controlling operation of the polishing apparatus, and a processor 9b configured to execute arithmetic operations according to instructions included in the programs. The memory 9a includes a main memory, such as a random access memory (RAM) and an auxiliary memory, such as a hard disk drive (HDD) or a solid state drive (SSD). Examples of the processor 9b include a CPU (Central Processing Unit) and a GPU (Graphics Processing Unit). However, the specific configuration of the operation controller 9 is not limited to these examples.

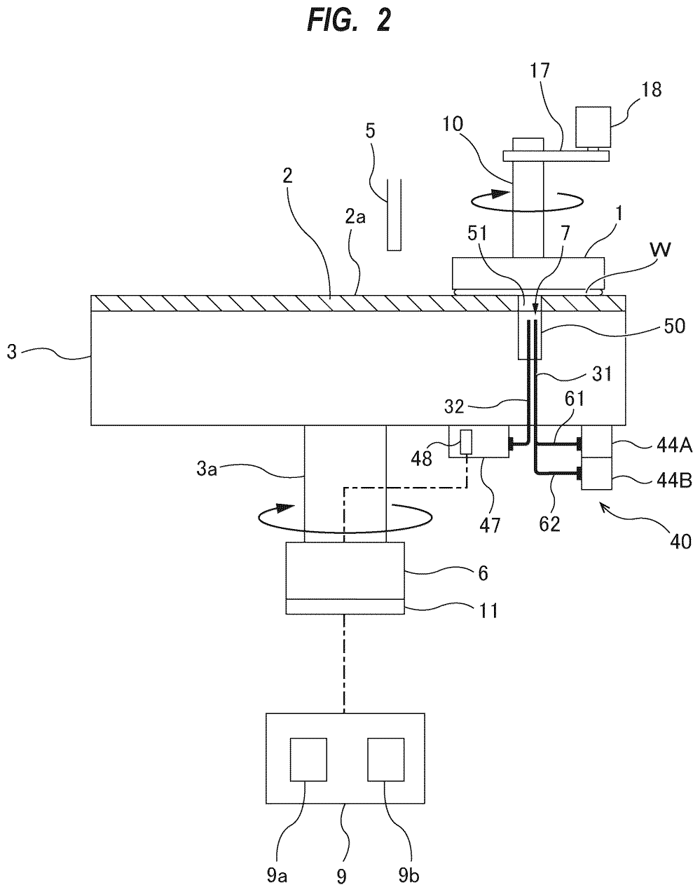

FIG. 2 is a cross-sectional view showing an embodiment of a detailed configuration of the polishing apparatus shown in FIG. 1. The head shaft 10 is coupled to a polishing-head motor 18 via a coupling element 17, such as belt, so that the head shaft 10 is rotated by the polishing-head motor 18. The rotation of the head shaft 10 in turn rotates the polishing head 1 in the direction indicated by the arrow.

The spectrometer 47 includes a photodetector 48. In one embodiment, the photodetector 48 is an image sensor, such as a CCD or a CMOS, or a photodiode. The optical sensor head 7 is optically coupled to the first flash light source 44A, the second flash light source 44B, and the photodetector 48. The photodetector 48 is electrically coupled to the operation controller 9. In FIG. 2, for the sake of explanation, the second flash light source 44B is depicted under the first flash light source 44A, but the arrangement of the first flash light source 44A and the second flash light source 44B is not particularly limited.

The optical film-thickness measuring system 40 further includes a light-emitting optical fiber cable 31 that guides the light emitted by the first flash light source 44A and the second flash light source 44B to the surface of the wafer W, and a light-receiving optical fiber cable 32 that receives reflected light from the wafer W and transmits the reflected light to the spectrometer 47. A distal end of the light-emitting optical fiber cable 31 and a distal end of the light-receiving optical fiber cable 32 are located within the polishing table 3.

The distal end of the light-emitting optical fiber cable 31 and the distal end of the light-receiving optical fiber cable 32 constitute the optical sensor head 7 that directs the light to the surface of the wafer W and receives the reflected light from the wafer W. The other end of the light-receiving optical fiber cable 32 is coupled to the spectrometer 47. The spectrometer 47 is configured to resolve the reflected light from the wafer W according to wavelength and measure intensities of the reflected light over a predetermined wavelength range.

The light-emitting optical fiber cable 31 is optically coupled to a first branch optical fiber cable 61 and a second branch optical fiber cable 62. An end of the first branch optical fiber cable 61 is coupled to the first flash light source 44A. An end of the second branch optical fiber cable 62 is coupled to the second flash light source 44B. The configurations of the light-emitting optical fiber cable 31, the first branch optical fiber cable 61, and the second branch optical fiber cable 62 are not particularly limited as long as the light-emitting optical fiber cable 31 is optically coupled to both the first branch optical fiber cable 61 and the second branch optical fiber cable 62. In one embodiment, two optical fiber cables constituting the first branch optical fiber cable 61 and the second branch optical fiber cable 62 may be joined to form the light-emitting optical fiber cable 31.

The first flash light source 44A and the second flash light source 44B transmit the light to the optical sensor head 7 at different timings through the light-emitting optical fiber cable 31, the first branch optical fiber cable 61, and the second branch optical fiber cable 62, so that the optical sensor head 7 emits the light toward the wafer W. The reflected light from the wafer W is received by the optical sensor head 7 and transmitted to the photodetector 48 of the spectrometer 47 through the light-receiving optical fiber cable 32. The spectrometer 47 decomposes or resolves the reflected light according to its wavelength and measures the intensity of the reflected light at each wavelength. The spectrometer 47 sends measurement data of the intensity of the reflected light to the operation controller 9.

The operation controller 9 generates a spectrum of the reflected light from the measurement data of the intensity of the reflected light. This spectrum indicates a relationship between the intensity of the reflected light and the wavelength, and a shape of the spectrum changes according to the film thickness of the wafer W. The operation controller 9 determines the film thickness of the wafer W from the spectrum of the reflected light. A known technique is used to determine the film thickness of the wafer W from the spectrum of the reflected light. For example, a Fourier transform is performed on the spectrum of the reflected light, and the film thickness is determined from a frequency spectrum obtained. In another example, the operation controller 9 searches a spectrum library storing multiple reference spectra associated with multiple film thicknesses, determines a reference spectrum having a shape closest to the spectrum of the reflected light, and determines a film thickness associated with the determined reference spectrum.

During polishing of the wafer W, the optical sensor head 7 emits the light onto a plurality of measurement points on the wafer W while moving across the surface of the wafer W on the polishing pad 2 and receives the reflected light from the wafer W each time the polishing table 3 makes one rotation. The operation controller 9 determines the film thickness of the wafer W from the measurement data of the intensity of the reflected light, and controls a polishing operation for the wafer W based on the film thickness. For example, the operation controller 9 determines a polishing end point at which the film thickness of the wafer W reaches a target film thickness.

The polishing table 3 has a hole 50 that opens in its upper surface. In addition, the polishing pad 2 has a through-hole 51 formed at a position corresponding to the hole 50. The hole 50 communicates with the through-hole 51, and the through-hole 51 opens in the polishing surface 2a. The optical sensor head 7, which is composed of the distal end of the light-emitting optical fiber cable 31 and the distal end of the light-receiving optical fiber cable 32, is disposed in the hole 50 and is located below the through-hole 51. In order to prevent the slurry from entering the hole 50, a flow of pure water may be formed in the hole 50, or the through-hole 51 may be blocked with a transparent window (not shown).

In this embodiment, xenon flash lamps are used as the first flash light source 44A and the second flash light source 44B. The optical sensor head 7, which is composed of the respective ends of the light-emitting optical fiber cable 31 and the light-receiving optical fiber cable 32, is disposed facing the wafer W held by the polishing head 1. Each time the polishing table 3 makes one rotation, the first flash light source 44A and the second flash light source 44B emit the light multiple times, and the optical sensor head 7 directs the light to the multiple measurement points on the wafer W. In this embodiment, only one optical sensor head 7 is provided, while a plurality of optical sensor heads 7 may be provided.

During polishing of the wafer W, the optical sensor head 7 moves across the wafer W each time the polishing table 3 makes one rotation. While the optical sensor head 7 is below the wafer W, the first flash light source 44A and the second flash light source 44B emit the light multiple times at different timings. The light is directed to the surface (surface to be polished) of the wafer W through the light-emitting optical fiber cable 31, the first branch optical fiber cable 61, and the second branch optical fiber cable 62, and the reflected light from the wafer W is received by the spectrometer 47 through the light-receiving optical fiber cable 32 and captured by the photodetector 48. The spectrometer 47 measures the intensity of the reflected light at each wavelength over a predetermined wavelength range, and transmits the obtained measurement data to the operation controller 9. This measurement data is a film-thickness signal that changes according to the film thickness of the wafer W. The operation controller 9 generates, from the measurement data, a spectrum of the reflected light representing the light intensity of each wavelength, and further determines the film thickness of the wafer W from the spectrum of the reflected light.

The rotary encoder 11 is electrically coupled to the operation controller 9. An output signal of the rotary encoder 11 (i.e., a detected value of the rotation angle of the polishing table 3) is sent to the operation controller 9. The operation controller 9 determines a relative position of the optical sensor head 7 with respect to the polishing head 1 from the output signal of the rotary encoder 11, i.e., the rotation angle of the polishing table 3, and controls emission timings of the first flash light source 44A, emission timings of the second flash light source 44B, and light detection timings of the spectrometer 47 based on the relative position of the optical sensor head 7.

During polishing of the wafer W, the operation controller 9 instructs the first flash light source 44A, the second flash light source 44B, and the spectrometer 47 to control the light-emission operations of the first flash light source 44A and the second flash light source 44B and the light detection operation of the spectrometer 47. Specifically, when the optical sensor head 7 is below the wafer W, the operation controller 9 transmits light-emission trigger signals to the first flash light source 44A and the second flash light source 44B, and transmits light-detection trigger signals to the spectrometer 47. When the first flash light source 44A and the second flash light source 44B receive the light-emission trigger signals, they instantaneously emit the light. When the spectrometer 47 receives the light-detection trigger signals, the spectrometer 47 starts capturing the reflected light, and when the transmission of the light-detection trigger signals are stopped, the spectrometer 47 stops capturing the reflected light.

The operation controller 9 generates the light-emission trigger signals and the light-detection trigger signals that are synchronized with each other. While the optical sensor head 7 moves across the wafer W, the first flash light source 44A and the second flash light source 44B receive the light-emission trigger signals and emit the light multiple times, and at the same time, the photodetector 48 of the spectrometer 47 receives the light-detection trigger signals and captures the reflected light from the wafer W multiple times.

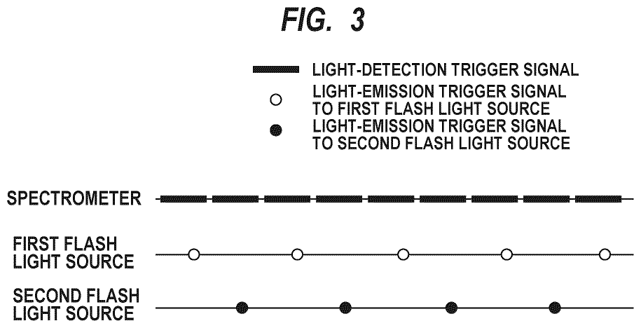

FIG. 3 is a time chart showing an embodiment of the light-emission operations of the first flash light source 44A and the second flash light source 44B, and the reflected-light capturing operation of the spectrometer 47. The first flash light source 44A and the second flash light source 44B alternately emit the light, while the spectrometer 47 captures the reflected light from the wafer W at the same timings as the first flash light source 44A and the second flash light source 44B emit the light. In the embodiment shown in FIG. 3, the first flash light source 44A and the second flash light source 44B emit the light at the same cycle (the same time intervals).

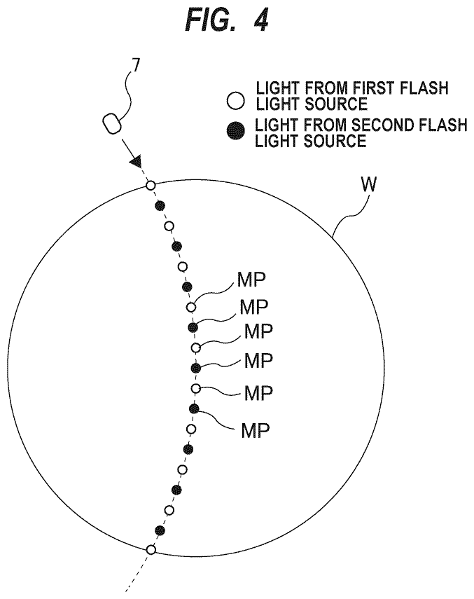

FIG. 4 is a diagram showing an example of light irradiation points on the surface of the wafer W. The light irradiation points correspond to measurement points MP for the film thickness of the wafer W. The operation controller 9 instructs the first flash light source 44A and the second flash light source 44B (i.e., sends the light-emission trigger signals to the first flash light source 44A and the second flash light source 44B) to cause the first flash light source 44A and the second flash light source 44B to emit the light multiple times at different timings, while the optical sensor head 7 is moving across the wafer W. As shown in FIG. 4, the light emitted from the first flash light source 44A and the second flash light source 44B is alternately casted on the surface of the wafer W.

Since the first flash light source 44A and the second flash light source 44B emit the light at different timings, the emission cycle of each of the first flash light source 44A and the second flash light source 44B can be increased. As a result, the intensity of light emitted from each of the first flash light source 44A and the second flash light source 44B is stabilized. Furthermore, since the light is emitted multiple times from both the first flash light source 44A and the second flash light source 44B while the optical sensor head 7 is moving across the surface of the wafer once, the film thickness of the wafer W can be measured at many measurement points MP.

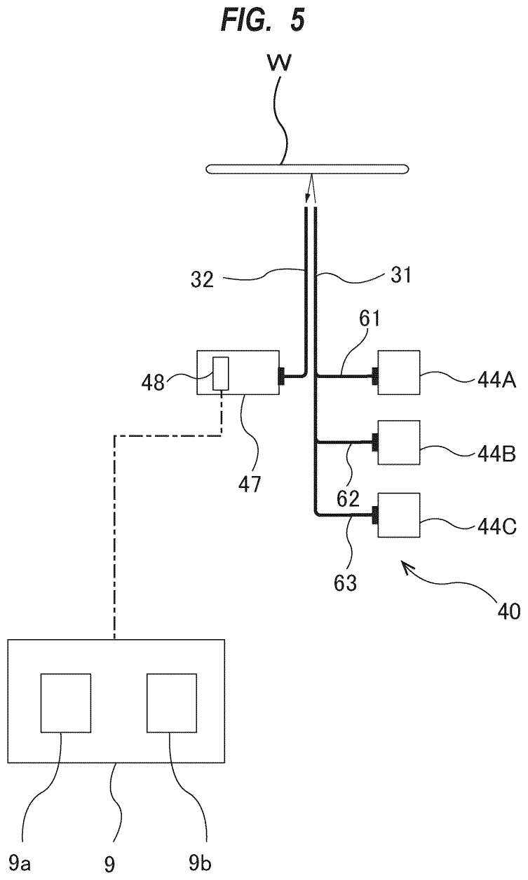

In one embodiment, the optical film-thickness measuring system 40 may further include one or more flash light sources in addition to the first flash light source 44A and the second flash light source 44B. For example, as shown in FIG. 5, the optical film-thickness measuring system 40 may include the first flash light source 44A, the second flash light source 44B, and a third flash light source 44C. The third flash light source 44C is coupled to a third branch optical fiber cable 63 optically coupled to the light-emitting optical fiber cable 31.

The operation controller 9 instructs the first flash light source 44A, the second flash light source 44B, and the third flash light source 44C to emit the light at different timings.

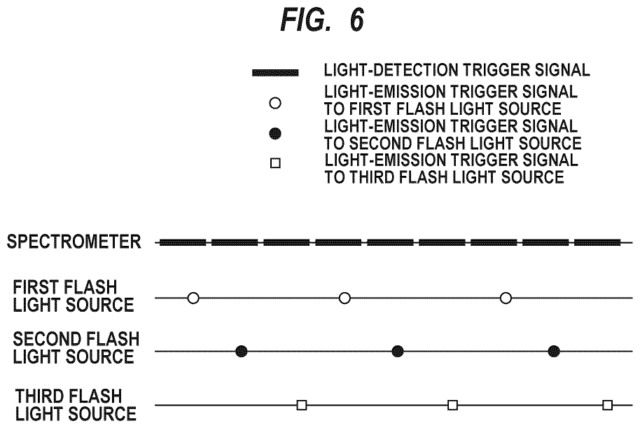

FIG. 6 is a time chart showing an embodiment of the light-emission operations of the three flash light sources 44A, 44B, and 44C and the reflected-light capturing operation of the spectrometer 47. As shown in FIG. 6, the three flash light sources 44A, 44B, and 44C repeatedly emit the light in the order of the first flash light source 44A, the second flash light source 44B, and the third flash light source 44C, and the spectrometer 47 captures the reflected light from the wafer W at the same timings as the three flash light sources 44A, 44B, and 44C emit the light. In the embodiment shown in FIG. 6, the flash light sources 44A, 44B, and 44C emit the light at the same cycle (the same time intervals).

The embodiment shown in FIGS. 5 and 6 is the same as the above embodiments with the two flash light sources 44A and 44B in that the three flash light sources 44A, 44B, and 44C emit the light at different timings while the optical sensor head 7 moves across the surface of the wafer W once. Furthermore, the embodiment with the three flash light sources 44A, 44B, and 44C is the same as the above embodiments with the two flash light sources 44A and 44B in that any two of the three flash light sources 44A, 44B, and 44C emit the light alternately while the optical sensor head 7 moves across the surface of the wafer W once. The embodiment with the three flash light sources 44A, 44B, and 44C can make the light emission cycle of each flash light source longer and/or can increase the number of film-thickness measurement points. Four or more flash light sources may be provided.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

What is claimed is:

1. A polishing method of polishing a substrate, comprising:
rotating a polishing table together with an optical sensor head, the optical sensor head being optically coupled to a spectrometer, a first flash light source, and a second flash light source;
while moving the optical sensor head across the substrate, polishing the substrate by pressing the substrate with a polishing head against a polishing pad on the polishing table;
causing the first flash light source and the second flash light source to emit light multiple times at different timings to cast the light on the substrate through the optical sensor head while the optical sensor head is moving across the substrate, and capture reflected light from the substrate through the optical sensor head by the spectrometer;
generating a spectrum of the reflected light; and
determining a film thickness of the substrate from the spectrum.

2. The polishing method according to claim 1, wherein the first flash light source and the second flash light source alternately emit the light while the optical sensor head is moving across the substrate.

3. The polishing method according to claim 1, wherein:
the optical sensor head is comprised of an end of a light-emitting optical fiber cable and an end of a light-receiving optical fiber cable;
the light-emitting optical fiber cable is coupled to a plurality of branch optical fiber cables; and
the first flash light source and the second flash light source are coupled to the plurality of branch optical fiber cables, respectively.

4. A polishing apparatus for polishing a substrate, comprising:
a polishing table configured to support a polishing pad;
a table motor configured to rotate the polishing table;
an optical sensor head disposed in the polishing table;
a spectrometer, a first flash light source, and a second flash light source optically coupled to the optical sensor head;
a polishing head configured to press the substrate against the polishing pad to polish the substrate; and
an operation controller configured to control operations of the spectrometer, the first flash light source, and the second flash light source, the operation controller being configured to:
instruct the first flash light source and the second flash light source to emit light multiple times at different timings to cast the light through the optical sensor head on the substrate while the optical sensor head is moving across the substrate, and instruct the spectrometer to capture reflected light from the substrate through the optical sensor head;
generate a spectrum of the reflected light; and
determine a film thickness of the substrate from the spectrum.

5. The polishing apparatus according to claim 4, wherein the operation controller is configured to instruct the first flash light source and the second flash light source to alternately emit the light while the optical sensor head is moving across the substrate.

6. The polishing apparatus according to claim 4, wherein:
the optical sensor head is comprised of an end of a light-emitting optical fiber cable and an end of a light-receiving optical fiber cable;
the light-emitting optical fiber cable is coupled to a plurality of branch optical fiber cables; and
the first flash light source and the second flash light source are coupled to the plurality of branch optical fiber cables, respectively.
